(19) United States
(12) Patent Application Publication
(10) Pub. No.: US 2010/0309649 A1
(43) Pub. Date: Dec. 9, 2010

(54) PHOTOELECTRONIC DEVICE HAVING A VARIABLE RESISTOR STRUCTURE

(75) Inventor: CHIA-LIANG HSU, Hsinchu County (CH)

Correspondence Address: Adli Law Group P.C., 633 West Fifth Street, Suite 2600, Los Angeles, CA, 90071, US

(73) Assignee: Epistar Corporation, Hsinchu (CN)

(21) Appl. No.: 12/794,126

(22) Filed: Jun. 4, 2010

(30) Foreign Application Priority Data
Jun. 9, 2009 (CN) 098119326

(51) Int. Cl. H01L 33/08; H01L 33/00; H05B 37/02; G09F 13/04

(52) U.S. Cl. 362/97.1; 257/88; 257/79; 315/52; 257/E33.001

(57) ABSTRACT

A photoelectronic device having a variable resistor structure includes a photoelectronic element array. The photoelectronic element array electrically connects with the variable resistor structure via a wire structure, wherein at least one resistor of the variable resistor structure is open.

### REFERENCE TO RELATED APPLICATION

This application claims the right of priority based on TW application Ser. No. 098119326, filed “Jun. 9, 2009”, entitled “PHOTOELECTRONIC DEVICE HAVING A VARIABLE RESISTOR STRUCTURE” and the contents of which are incorporated herein by reference in its entirety.

### TECHNICAL FIELD

The application relates to a photoelectronic device, and more particularly to a photoelectronic device having a variable resistor structure.

### DESCRIPTION OF BACKGROUND ART

The photoelectronic element includes many types such as light-emitting diode (LED), solar cell, or photo diode. Taking LED array for example, there are a lot of applications for an LED array, such as illumination devices or displays. Depending on the applications, the operating voltage or the operating current for the LED array is different. Thus, the LED array can electrically connect with several resistors to adjust the voltage or the current.

In general, the resistivity of the resistors can be adjusted by laser trimming before the LED array electrically connects with the resistors. As FIG. 7 shows, for accurately adjusting the resistivity of the resistor 70, the in-situ probing is utilized to measure the voltage or the current of the resistor 70. The route 72 for the laser to trim the resistor 70 is decided by the measurement result. The laser trimming does not stop until reaching the predetermined voltage or current. The manufacturing efficiency, however, can not be improved because it takes time and labors to do accurate pointing and laser trimming at the same time.

Each of the foregoing photoelectronic elements can further connect a substrate thereof to a base via solders or adhesive elements. Moreover, the base includes at least a circuit to electrically connect with a contact of the photoelectronic element via a conductive structure, such as wire lines.

### SUMMARY OF THE DISCLOSURE

According to a first embodiment of present application, a photoelectronic device having a variable resistor structure includes a substrate and a photoelectronic element array formed on the substrate, wherein the photoelectronic element array includes a first photoelectronic element, a second photoelectronic element, a third photoelectronic element, and a forth photoelectronic element that are electrically connected in series. The photoelectronic element array is electrically connected with a third electrode and the variable resistor structure via a wire structure, wherein the variable resistor structure contains at least a resistor which is open.

A second embodiment of present application is similar to the first embodiment. The difference therebetween is the photoelectronic elements of the photoelectrical element array are electrically connected in parallel.

A third embodiment of present application is similar to the first embodiment. The difference therebetween is that the third embodiment further includes a submount and a fifth electrode, wherein the photoelectronic element array and the substrate thereof are located on the submount. The variable resistor structure is also located on the submount and electrically connected with the photoelectronic element array via the fifth electrode.

### BRIEF DESCRIPTION OF THE DRAWINGS

FIG. 1 illustrates a diagram of a photoelectronic device in accordance with a first embodiment of the present application.

FIGS. 2A-2B illustrate diagrams of a variable resistor structure in accordance with the present application.

FIG. 3 illustrates a diagram of a photoelectronic device in accordance with a second embodiment of the present application.

FIG. 4 illustrates a diagram of a photoelectronic device in accordance with a third embodiment of the present application.

FIG. 5 illustrates a diagram of a light-generating device adopting any one of the embodiments of present application.

FIG. 6 illustrates a diagram of a backlight module adopting any one of the embodiments of present application.

FIG. 7 illustrates a diagram showing a route for a laser traveling on the resistor.

FIG. 8 illustrates a cross-sectional view of a photoelectronic element in accordance with a first embodiment of the present application.

### DETAILED DESCRIPTION OF PREFERRED EMBODIMENTS

The embodiments of present application will be described in detail and sketched in figures. The same or similar parts will be shown with the same numbers in every figure and the specification.

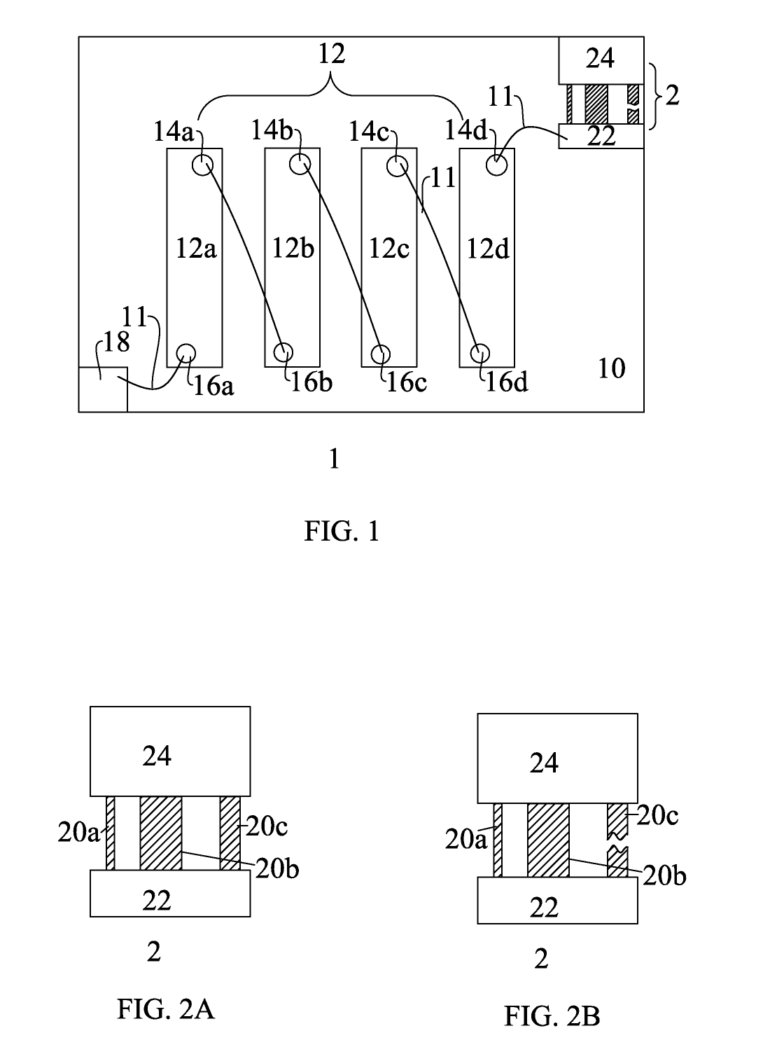

As FIG. 1 shows, a first embodiment of a photoelectronic device 1 having a variable resistor structure includes a substrate 10; a photoelectronic element array 12 formed on the substrate 10, wherein the photoelectronic element array 12 includes a first photoelectronic element 12a, a second photoelectronic element 12b, a third photoelectronic element 12c, and a forth photoelectronic element 12d. When the photoelectronic elements are electrically connected in series, for example, a first electrode 14a of the first photoelectronic element 12a, a first electrode 14b of the second photoelectronic element 12b, and a first electrode 14c of the third photoelectronic element 12c are electrically connected with a second electrode 16b of the second photoelectronic element 12b, a second electrode 16c of the third photoelectronic element 12c, and a second electrode 16d of the forth photoelectronic element 12d respectively via a wire structure 11, wherein the polarity of each first electrode is different from that of each second electrode. A third electrode 18 is located on the substrate 10 and electrically connected with a second electrode 16a of the first photoelectronic element 12a via the wire structure 11. A variable resistor structure 2 is located on the substrate 10 and electrically connected in series with a first electrode 14d of the forth photoelectronic element 12d via the wire structure 11, wherein the variable resistor structure contains at least a resistor which is open. The above four photoelectronic elements are for instance and the amount of the photoelectronic elements can be adjusted based on its application.

As FIG. 8 shows, each photoelectronic element includes at least a semiconductor stacked layer. The semiconductor stacked layer of the first photoelectronic element 12a includes a first semiconductor layer 122 located on the substrate 10, a second semiconductor layer 126 located on the first semiconductor layer 122, and an active layer 124 located between the first semiconductor layer 122 and the second semiconductor layer 126. The semiconductor stacked layer can generate light and includes a semiconductor material containing more than one element selected from a group consisting of Ga, Al, In, As, P, N, Zn, Cd, and Se.

As FIG. 2A shows, the variable resistor structure 2 includes a first resistor 20a, a second resistor 20b, and a third resistor 20c, wherein the resistivities of the first resistor 20a, the second resistor 20b, and the third resistor 20c can be the same or different. A forth electrode 22 is electrically connected with the first resistor 20a, the second resistor 20b, and the third resistor 20c, and a fifth electrode 24 is electrically connected with the first resistor 20a, the second resistor 20b, and the third resistor 20c, wherein the first resistor 20a, the second resistor 20b, and the third resistor 20c are electrically connected in parallel. The forth electrode 22 directly contacts with one end of each of the first resistor 20a, the second resistor 20b, and the third resistor 20c, and the fifth electrode 24 directly contacts with the other end of each of the first resistor 20a, the second resistor 20b, and the third resistor 20c. The electrical connection is not limited to direct contact and can be formed via wire structure 11, for example. The above three resistors are for instance and the amount of the resistors can be adjusted based on its application. In addition, as FIG. 1 shows, the forth electrode 22 is electrically connected with the photoelectronic element array 12 and the fifth electrode 24 is electrically connected with the external circuit (not shown). The external circuit can be printed circuit board (PCB).

The first embodiment can reach the operating voltage or the operating current of the application by adjusting the resistivity of the variable resistor structure 2. For reaching the operating voltage of the application, steady current is input to the photoelectronic device 1 to measure the voltage value thereof. According to the measured voltage value, the resistivity of the variable resistor structure 2 is adjusted to reach the operating voltage of the photoelectronic device 1 based on its application. The method of adjusting the resistivity of the variable resistor structure 2 includes laser trimming which breaks at least one resistor of the variable resistor structure 2, as FIG. 2B shows. The predetermined operating voltage of the photoelectronic device is, for example, 3.2V. A steady current, 20 mA for example, is input to the photoelectronic device 1 and the measured voltage value of the photoelectronic device 1 is then 3V. The resistivities of the first resistor 20a, the second resistor 20b, and the third resistor 20c are 150Ω, 50Ω, and 100Ω, respectively. The resistivity of the variable resistor structure 2 when the first resistor 20a, the second resistor 20b, and the third resistor 20c are in parallel connection is 27.3Ω. The resistivity of the variable resistor structure 2 when the first resistor 20a and the second resistor 20b are in parallel connection is 37.5 Ω after the third resistor 20c is broken by laser trimming. A steady current, 20 mA for example, is input to the photoelectronic device 1 then and the measured voltage value thereof can reach the predetermined operating voltage, 3.2V. The photoelectronic element array 12 and the variable resistor structure 2 can be electrically connected in series or parallel based on the requirement of the application.

The material of the third electrode 18, the forth electrode 22, and the fifth electrode 24 can be metal to receive external voltage, such as Cu, Al, In, Sn, Au, Pt, Zn, Ag, Ti, Pb, Pd, Ge, Ni, Cr, Cd, Co, Mn, Sb, Bi, Ga, Tl, Po, Ir, Re, Rh, Os, W, Li, Na, K, Be, Mg, Ca, Sr, Ba, Zr, Mo, La, Cu—Sn, Cu—Zn, Cu—Cd, Sn—Pb—Sb, Sn—Pb—Zn, Ni—Sn, Ni—Co, or Au Alloy and so on. The material of the first resistor 20a, the second resistor 20b, and the third resistor 20c can be metal such as Cu, Al, In, Sn, Au, Pt, Zn, Ag, Ti, Pb, Pd, Ge, Ni, Cr, Cd, Co, Mn, Sb, Bi, Ga, Tl, Po, Ir, Re, Rh, Os, W, Li, Na, K, Be, Mg, Ca, Sr, Ba, Zr, Mo, La, Cu—Sn, Cu—Zn, Cu—Cd, Sn—Pb—Sb, Sn—Pb—Zn, Ni—Sn, Ni—Co, or Au Alloy and so on, wherein the resistivity of the variable resistor structure 2 can be adjusted.

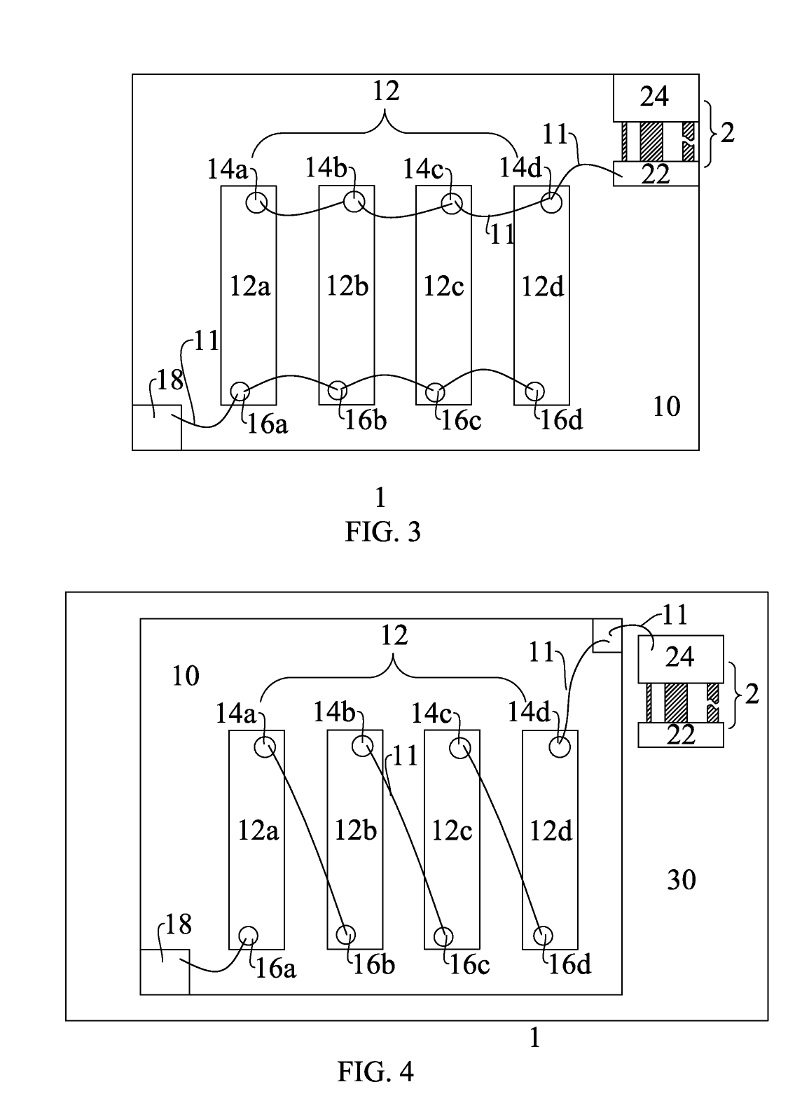

FIG. 3 shows a second embodiment which is similar to the first embodiment. The difference is that each photoelectronic element of the photoelectrical element array 12 is connected in parallel. FIG. 4 shows a third embodiment which is similar to the first embodiment. The difference is that the third embodiment further includes a submount 30 for the photoelectronic element array 12 and the substrate 10 to locate thereon. The variable resistor structure 2 is also located on the submount 30 and electrically connected with the photoelectronic element array 12 via the fifth electrode 24.

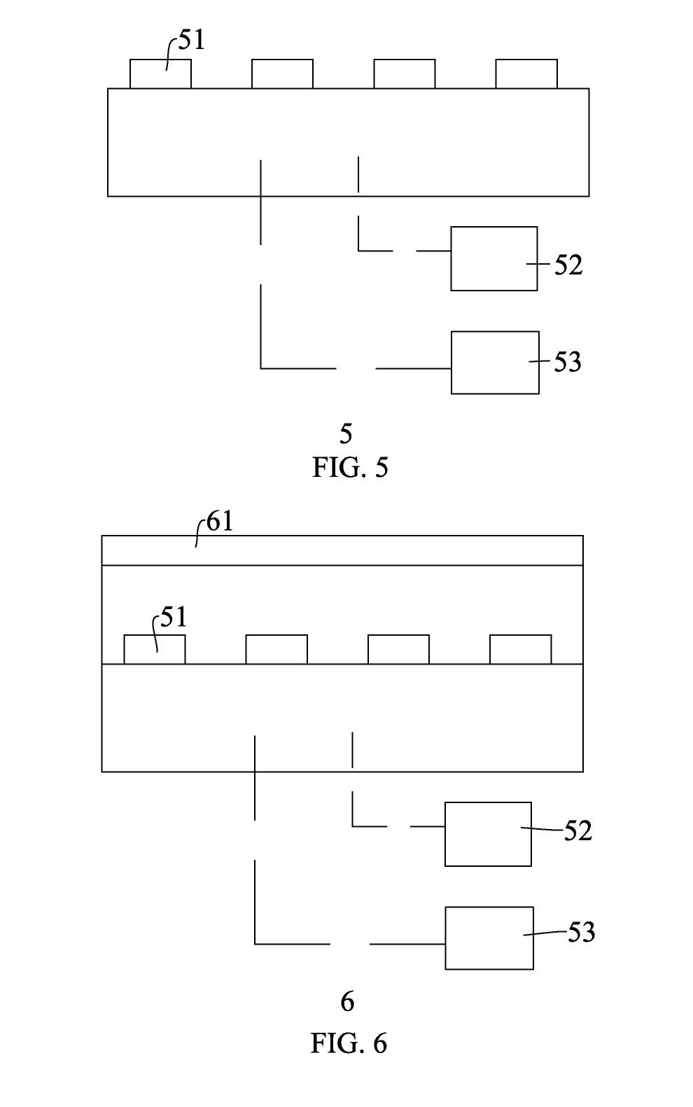

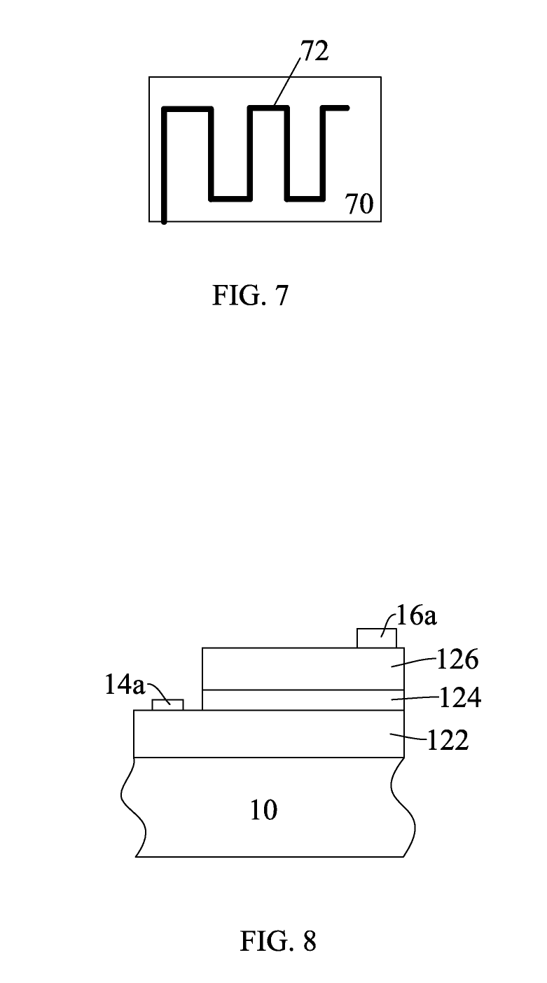

FIG. 5 illustrates a diagram of a light-generating device. A light-generating device 5 includes a chip manufactured by a wafer containing the photoelectronic structure of any one of the embodiments of the present application. A light-generating device 5 can be an illumination device such as a street light, a lamp of vehicle, or an illustration source for interior. The light-generating device 5 can be also a traffic sign, or a backlight of a backlight module of an LCD. The light-generating device 5 includes a light source 51 adopting the foregoing photoelectronic devices; a power supplying system 52 providing current to the light source 51; and a control element 53 controlling the power supplying system 52.

FIG. 6 illustrates a cross-sectional schematic diagram of a back light module 6. A back light module 6 includes the light-generating device 5 of the foregoing embodiment, and an optical element 61. The optical element 61 can process the light generated by the light-generating device 5 for LCD application, such as scattering the light emitted from the light-generating device 5.

Although the present application has been explained above, it is not the limitation of the range, the sequence in practice, the material in practice, or the method in practice. Any modification or decoration for present application is not detached from the spirit and the range of such.

What is claimed is:

1. A photoelectronic device, comprising:
a photoelectronic element array; and
a variable resistor structure electrically connected with the photoelectronic element array, comprising a plurality of resistors, wherein at least one of the plurality of resistors is open.

2. The photoelectronic device of claim 1, wherein the photoelectronic element array comprises a plurality of photoelectronic elements.

3. The photoelectronic device of claim 2, wherein the plurality of photoelectronic elements is electrically connected in series or parallel.

4. The photoelectronic device of claim 2, wherein the photoelectronic element comprises an LED.

5. The photoelectronic device of claim 2, wherein the photoelectronic element comprises a semiconductor stacked layer, comprising:
a first semiconductor layer;
a second semiconductor layer formed on the first semiconductor layer; and
an active layer formed between the first semiconductor layer and the second semiconductor layer.

6. The photoelectronic device of claim 1, wherein the variable resistor structure and the photoelectronic element array are electrically connected in series to adjust the operating voltage of the photoelectronic element array.

7. The photoelectronic device of claim 1, wherein the variable resistor structure and the photoelectronic element array are electrically connected in parallel to adjust the operating current of the photoelectronic element array.

8. The photoelectronic device of claim 1, wherein at least one resistor of the variable resistor structure is open by laser trimming based on the operating voltage or the operating current for application.

9. The photoelectronic device of claim 1, wherein the plurality of resistors is electrically connected in parallel.

10. The photoelectronic device of claim 1 further comprising a submount supporting the photoelectronic element array and the variable resistor structure.

11. The photoelectronic device of claim 10, wherein the submount comprises a PCB.

12. A photoelectronic device, comprising:
a photoelectronic element; and
a variable resistor structure electrically connected with the photoelectronic element, comprising a plurality of resistors, wherein at least one of the plurality of resistors is open.

13. The photoelectronic device of claim 12, wherein the plurality of resistors is electrically connected in parallel.

14. The photoelectronic device of claim 12 further comprising a submount supporting the photoelectronic element and the variable resistor structure.

15. The photoelectronic device of claim 14, wherein the submount comprises a PCB.

16. The photoelectronic device of claim 12, wherein the variable resistor structure is electrically connected with the photoelectronic element in series or parallel.

17. The photoelectronic device of claim 12, wherein the photoelectronic element comprises an LED.

18. The photoelectronic device of claim 12, wherein the photoelectronic element comprises:
a first semiconductor layer;
a second semiconductor layer formed on the first semiconductor layer; and
an active layer formed between the first semiconductor layer and the second semiconductor layer.

19. A light-generating device comprising:
a light source comprising any one of the photoelectronic devices of claim 1-18;
a power supplying system providing current to the light source; and
a control element controlling the power supplying system.

20. A back light module comprising:
a light-generating device comprising any one of the photoelectronic devices of claim 1-18; and
an optical element processing the light generated by the light-generating device.
